(19) United States
(12) Patent Application Publication
(10) Pub. No.: US 2018/0110145 A1
(43) Pub. Date: Apr. 19, 2018

(54) DISPLAY UNIT AND DISPLAY APPARATUS HAVING THE SAME

(71) Applicant: SAMSUNG ELECTRONICS CO., LTD., Suwon-si (KR)

(72) Inventors: Hyun Yong CHOI, Suwon-si (KR); Ha Na KIM, Suwon-si (KR); Jun Yong PARK, Suwon-si (KR); Jee Hoon PARK, Seoul (KR); You Na CHOO, Seongnam-si (KR); Soo Hyun WHANG, Seoul (KR); Jun Ki NOH, Suwon-si (KR)

(73) Assignee: SAMSUNG ELECTRONICS CO., LTD., Suwon-si (KR)

(21) Appl. No.: 15/725,441

(22) Filed: Oct. 5, 2017

(30) Foreign Application Priority Data
Oct. 17, 2016 (KR) 10-2016-0134598

(51) Int. Cl. H05K 5/02; H05K 5/00

(52) U.S. Cl. CPC H05K 5/0234; H05K 5/0204; H05K 5/0017

(57) ABSTRACT

The display apparatus includes a display unit configured to display content, the display unit having a first accommodating portion being depressed in a rear surface of the display unit, the first accommodating portion configured to accommodate a first portion of a cable connected to the display unit, a first guide portion depressed in the rear surface of the display unit, the first guide portion, into which a second portion different from the first portion of the cable is inserted, the first guide portion configured to guide the second portion of the cable from the first accommodating portion to a side of the display unit; and a stand detachably coupled to the display unit and configured to support the display unit on a mounting surface.

### CROSS-REFERENCE TO RELATED APPLICATION

This application claims priority from Korean Patent Application No. 10-2016-0134598, filed on Oct. 17, 2016, in the Korean Intellectual Property Office, the disclosure of which is incorporated herein by reference in its entirety.

### BACKGROUND

### 1. Field

Exemplary embodiments of the present disclosure relate to a display unit and display apparatus including the display unit, and more particularly, to a display unit which is provided to be close with a wall (or in contact) and the display apparatus including the display unit.

### 2. Description of the Related Art

Recently, in a display apparatus, a display unit to display content is provides high resolution and is increasing in size. The display unit is also becoming thinner and lighter in weight. The display apparatus includes a wall-mounted type display apparatus fixed on the wall and a stand type display apparatus standing on the floor.

The stand type display apparatus may include a stand for supporting the display unit so that the display unit may stand on the floor. In the related art, the stand is mounted on the lower end portion of the display unit and may include a portion extending along the front-rear direction of the display unit to support the display unit.

Recently, a display apparatus which may be used as the wall-mount type or the stand type depending on the needs of the user is proposed. This type of display apparatus, however, has a problem with the stand when used as the wall mounted type because the stand extends along the front-rear direction, hindering the display device from closely adhering to the wall and the stand needs to be removed to hang the display unit on the wall.

This gap between the display unit and the wall fails to give the user a feeling of integration between the display unit and the wall, and makes the back of the display unit exposed to the user from above, below, left and right, making it unpleasant to the sight.

### SUMMARY

One aspect of the present disclosure discloses a display apparatus capable of bringing a display unit into contact with a wall or bring the display unit to a proximity to the wall.

Another aspect of the present disclosure discloses a display apparatus that may be used as the stand type and the wall-mounted type, and may be installed to contact the wall or brought to close proximity of the wall when used as the stand type and the wall-mount type.

Still another aspect of the present disclosure discloses a display apparatus that may be installed to contact the wall or brought to close proximity of the wall without detaching the stand.

In accordance with an aspect of an exemplary embodiment, there is provided a display apparatus including a display unit configured to display content, the display unit having a first accommodating portion being depressed in a rear surface of the display unit, the first accommodating portion configured to accommodate a first portion of a cable connected to the display unit, a first guide portion depressed in the rear surface of the display unit, the first guide portion, into which a second portion different from the first portion of the cable is inserted, the first guide portion configured to guide the second portion of the cable from the first accommodating portion to a side of the display unit, and a stand detachably coupled to the display unit and configured to support the display unit on a mounting surface.

The stand may comprise a first supporting member configured to support the display unit, the first supporting member extending in a first direction from the display unit and configured to pivot on the display unit, and a second supporting member configured to support the display unit, the second supporting member extending in a second direction opposite to the first direction from the display unit or overlapping with the first supporting member to support the display unit with the first supporting member by extending in the first direction.

The stand may be made with transparent material.

The stand may be configured to be set to a first stand mode to allow the display unit to be placed on a floor, a second stand mode to allow the display unit to be disposed on the floor and brought close to a wall or brought in contact with the wall, and a wall mounted mode to allow the display unit to be hung on the wall.

The first supporting member may be configured to support the display unit by being extending in the first direction and wherein the second supporting member may be configured to support the display unit by extending in the second direction, in response to the stand being set in the first stand mode.

The second supporting member may be accommodated in the first supporting member and may be configured to support the display unit by extending the first direction together with the first supporting member, in response to the stand being set in the second stand mode.

The second supporting member may be accommodated in the first supporting member and may be directed to a third direction different from the first direction and the second direction together with the first supporting member, in response to the stand being set in the wall mounted mode.

The second supporting member may be rotatably coupled to the first supporting member.

The stand may include a connecting member having a fixing portion to which the first supporting member is rotatably coupled, the fixing portion being fixed to the display unit, and the first supporting member may include a rotation restricting portion configured to guide rotation of the first supporting member.

The first supporting member may include a supporting member accommodating portion provided on a lower surface of the first supporting member and configured to accommodate the second supporting member in response to the second supporting member overlapping the first supporting member.

The first supporting member may include a coupling groove to which the second supporting member is rotatably coupled, the coupling groove being provided in the supporting member accommodating portion.

The first guide portion may be configured to guide the cable to the stand provided on the lower side of the display unit, and the stand may include a second guide portion configured to guide the cable guided by the first guide portion to a lower portion of the stand.

At least one of the first accommodating portion and the first guide portion may be configured to have a minimum depth corresponding to a thickness of the cable.

The first guide portion may include an escape preventing portion protruding from an inner surface of the first guide portion, the escape preventing portion configured to prevent the cable from escaping out of the first guide portion.

The display unit may include a side frame made with a transparent material.

In accordance with an aspect of another exemplary embodiment, there is provided a display unit including a frame, a first accommodating portion having a connector configured to be connected to a cable, and the first accommodating portion being formed on a rear surface to accommodate a first portion of the cable connected to the connector, a second accommodating portion formed at an upper portion of the rear surface to accommodate a wall mount, and a first guide portion provided on the rear surface to insert a second portion different from the first portion of the cable, the first guide portion provided to guide the second portion of the cable from the first accommodating portion to a side of the frame, wherein a remaining portion of the rear surface other than portions of the rear surface where the first accommodating portion, the second accommodating portion, and the first guide portion are formed is in contact with a wall or in proximity of the wall when the display unit is mounted on the wall.

The first guide portion may include a groove depressed in the rear surface.

At least one of the first accommodating portion and the first guide portion may be configured to have a minimum depth corresponding to the thickness of the cable.

The first guide portion may include an escape preventing portion protruding from an inner surface of the first guide portion, the escape preventing portion configured to prevent the cable from escaping out of the first guide portion.

The frame may be made with a transparent material.

### BRIEF DESCRIPTION OF THE DRAWINGS

The above and/or other aspects of the disclosure will become apparent and more readily appreciated from the following description of the embodiments, taken in conjunction with the accompanying drawings of which:

FIG. 1 is a perspective view illustrating a display unit of a display apparatus standing on the floor, according to an embodiment of the present disclosure;

FIG. 2 is a perspective view illustrating a stand of the display apparatus shown in FIG. 1;

FIGS. 3 and 4 are exploded perspective views illustrating the stand shown in FIG. 2;

FIG. 5 is a perspective view illustrating a rear surface of the display unit of the display apparatus shown in FIG. 1;

FIG. 6 is a perspective view illustrating the display unit of the display apparatus shown in FIG. 1 in close contact with the wall while standing on the floor;

FIG. 7 is a perspective view illustrating the display unit of the display apparatus shown in FIG. 1 installed in close contact with the wall;

FIG. 8 is a perspective view illustrating a display unit of the display apparatus shown in FIG. 7 installed by a wall mount to closely contact the wall; and

FIG. 9 is a perspective view illustrating a stand separated from the display unit in the display apparatus shown in FIG. 7.

### DETAILED DESCRIPTION

Configurations illustrated in embodiments and the drawings described in the present specification are only exemplary embodiments of the present disclosure, and thus it is to be understood that various modified examples, which may replace the embodiments and the drawings described in the present specification, are possible when filing the present application.

Also, like reference numerals or symbols provided in the drawings of the present specification represent members or components that perform substantially the same functions.

The terms used in the present specification are used to describe exemplary embodiments of the present disclosure. Accordingly, it should be apparent to those skilled in the art that the following description of exemplary embodiments of the present disclosure is provided for illustration purpose only and not for the purpose of limiting the present disclosure as defined by the appended claims and their equivalents. It is to be understood that the singular forms “a,” “an,” and “the” include plural referents unless the context clearly dictates otherwise. It will be understood that when the terms “includes,” “comprises,” “including,” and/or “comprising,” when used in this specification, specify the presence of stated features, figures, operations, components, or combination thereof, but do not preclude the presence or addition of one or more other features, figures, steps, components, members, or combinations thereof.

Content may be displayed in a display apparatus. For example, the content may include a video file or an audio file played by a video player, which is one of applications, a music file played by a music player, a photo file displayed in a photo gallery, a web page file displayed by a web browser, and the like. The content may also include broadcasts received.

The content may include a video file, an audio file, a text file, an image file, or a web page to be displayed or executed in an application. The content may also include a video file and/or audio file included in a received broadcast signal.

In an embodiment of the present disclosure, content received from outside or stored content may include a broadcast signal, a video file, an audio file, a text file, an image file, or a web page to be executed in response to a user input (e.g. a touch, etc.). The term video may be used in the same sense as a moving image.

The content may include an application screen to be executed and a user interface constituting the application screen. The content may also include a single content or a plurality of contents.

An application refers to software running on a desk-top Operating system (OS), a mobile OS, or a display apparatus OS to be used by a user. For example, the application may include a word processor, a spreadsheet, a contacts application, a calendar application, a memo application, an alarm application, a social network system (SNS) application, a chatting application, a map application, a music player, or a video player. An application according to an embodiment of the present disclosure may mean software executable in a display apparatus in response to an input received from the user. An application according to an embodiment of the present disclosure may be software downloaded from outside of the display apparatus and executed in in the display apparatus.

It will be understood that, although the terms first, second, etc. may be used herein to describe various components, these components should not be limited by these terms. These terms are only used to distinguish one component from another. For example, a first component could be termed a second component, and, similarly, a second component could be termed a first component, without departing from the scope of the present disclosure. As used herein, the term “and/or” includes any and all combinations of one or more of associated listed items.

The terms “forward”, “rearward”, “upper portion”, “lower portion”, “upper side”, “lower side”, and the like used in the following descriptions are defined based on the drawings, and do not limit the shape and position of the components.

Hereinafter, the embodiments of the present disclosure will be described in detail with reference to the accompanying drawings in detail.

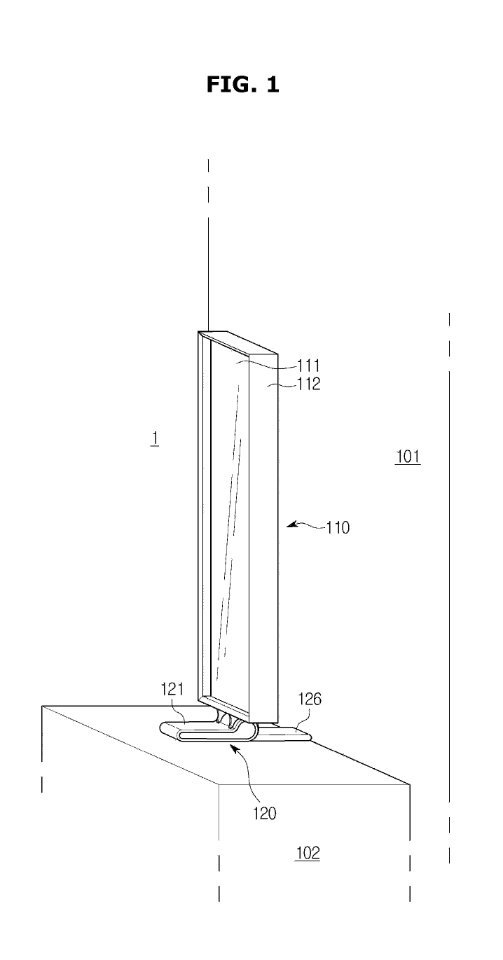

FIG. 1 is a perspective view illustrating a display unit 110 of a display apparatus 1 standing on a floor 102, according to an embodiment of the present disclosure.

Referring to FIG. 1, the display apparatus 1 according to an embodiment of the present disclosure will be described. The display apparatus 1 may include a display unit 110 and a stand 120.

The display unit 110 may be configured to display content, and the stand 120 may be provided to support the display unit 110 so that the display unit 110 may stand on the floor 102. It will be readily understood by those skilled in the art that the components included in the display apparatus 1 may be changed in response to slimming down the display apparatus 1.

The display unit 110 may include a display panel 111 on which the content is displayed and may include a side frame 112 that supports at least a portion of a side portion of the display panel 111. Here, the side frame 112 may be provided to include a material having transparency for the display apparatus 1 to give an impression of being integrated with the surrounding environment.

The display unit 110 is one of output devices to visually and/or audibly output content and may include a liquid crystal panel (LCD), an light emitting diode (LED) panel, or an organic LED panel. The display unit 110 may stand on the floor 102 by the support of the stand 120, or may be installed on a wall 101 by a wall mount 103 due to its thin thickness. Since the wall 101 and the floor 102 are the surfaces on which the display unit 110 is installed, they may also be referred to as installation surfaces 101 and 102.

The stand 120 is detachably coupled to the display unit 110 at the lower end portion of the display unit 110 and may support the display unit 110 so that the display unit 110 stands on the floor 102. That is, the stand 120 may support the display unit 110 so that the display unit does not fall when the display unit 110 is placed on the floor 102. The stand 120 may include a first supporting member 121 and a second supporting member 126. Details of the stand 120 will be described later.

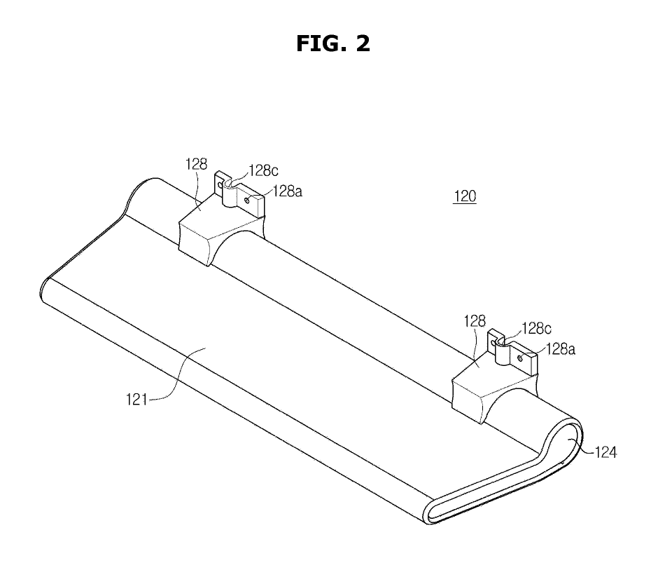

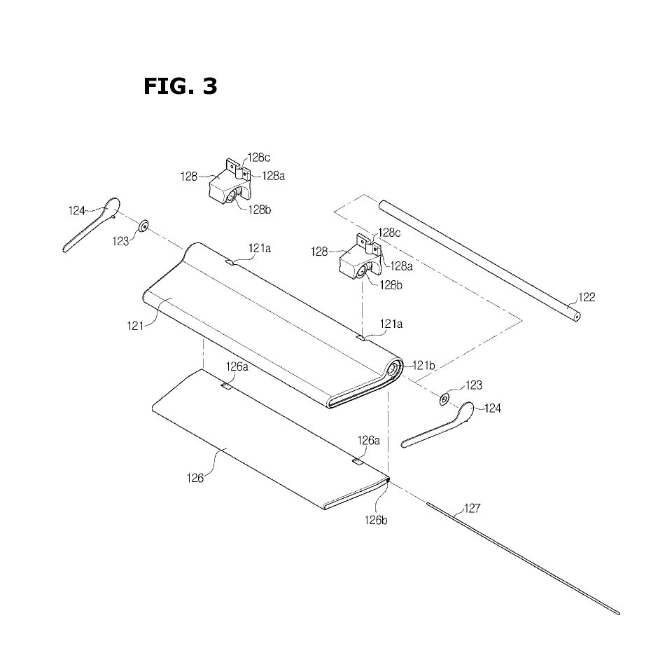

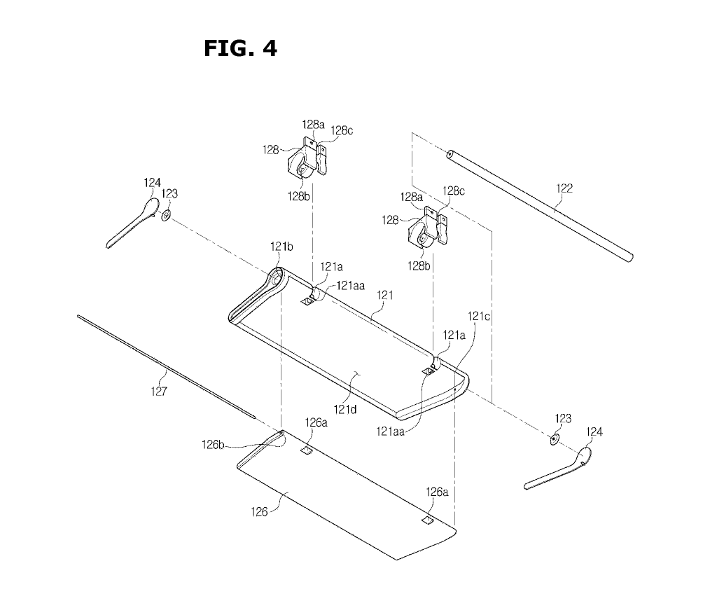

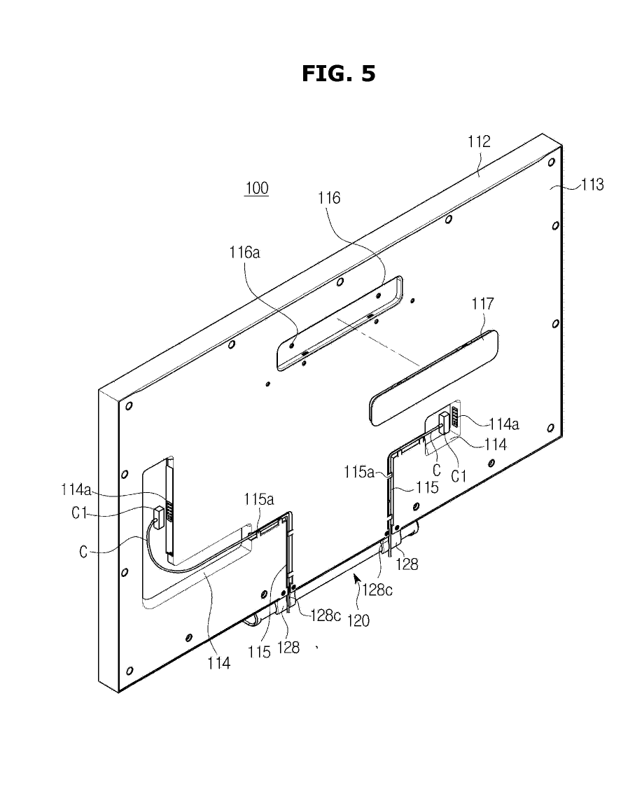

FIG. 2 is a perspective view illustrating a stand 120 of the display apparatus 1 shown in FIG. 1. FIGS. 3 and 4 are exploded perspective views illustrating the stand 120 shown in FIG. 2. FIG. 5 is a perspective view illustrating a rear surface 113 of the display unit 110 of the display apparatus 1 shown in FIG. 1.

Referring to FIG. 2, the stand 120 may support the display unit 110 so that the display unit 110 may stand on the floor 102. The stand 120 may include a material having transparency to prevent the display apparatus 1 from being alienated from the surrounding environment. That is, the display apparatus 1 according to an embodiment of the present disclosure may give a feeling of being integrated with the surrounding environment.

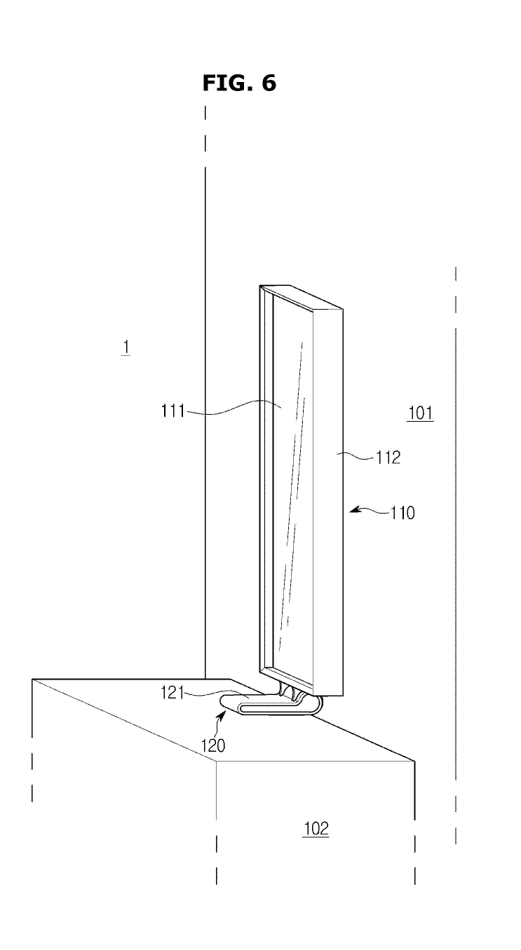

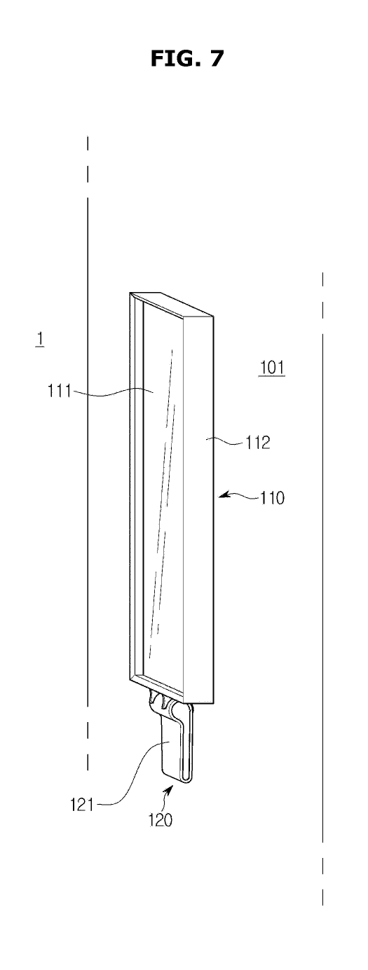

The stand 120 may be provided to be set to a first stand mode, in which the display unit 110 disposed on the floor 102 stands on the floor 102 as shown in FIG. 1, a second stand mode, in which the display unit 110 disposed on the floor 102 is installed closely to the wall as shown in FIG. 6, and a wall mounted mode, in which the display unit 110 is hung on the wall 101 to be closely attached thereto as shown in FIG. 7. For this, the stand 120 may include a first supporting member 121 to support the display unit 110 from the front, a second supporting member 126 to support the display unit 110 from the back, and a connecting member 128 to be fixed on the display unit 110.

When the display apparatus 1 is placed on the floor, that is, when the stand 120 is set to the first stand mode or the second stand mode, the first supporting member 121 is arranged to support the display unit 110 from the front. On the other hand, when the display apparatus 1 is used in the wall mounted type, that is, when the stand 120 is set to the wall mounted mode, the first supporting member 121 may pivot on the display unit 110 to be directed down from the display unit 110. At this time, the first supporting member 121 may be in contact with the wall 101 or brought to close proximity of the wall 101 (hereinafter “close contact” or “closely contact”).

The first supporting member 121 may be rotatable about the display unit 110. Specifically, the first supporting member 121 may include a connecting member groove 121a for one end portion of the first supporting member 121 to be rotatably coupled to a connecting member 128. That is, the first supporting member 121 may be rotatably coupled to the connecting member 128 as the first shaft 122 is inserted into the first coupling hole 121b while a portion of the connecting member 128 is inserted into the connecting member groove 121a.

Also, the first supporting member 121 may include a rotation restricting portion 121aa to restrict the rotation range with respect to the connecting member 128. The rotation restricting portion 121aa may be formed on the outer circumferential surface of the first coupling hole 121b, and may be restricted from being moved by a portion of the inner side of the connecting member 128 when the first supporting member 121 rotates counterclockwise by a predetermined angle with respect to the connecting member 128. The first supporting member 121 may be rotated to a range in which the rotation restricting portion 121aa is directed down from the display unit 110.

On the other hand, the rotation of the first supporting member 121 may be restricted as the tip portion of the connecting member 128 contacts the upper surface of the first supporting member 121 when the first supporting member 121 rotates clockwise with respect to the connecting member 128. At this time, the first supporting member 121 may be rotated to face forward from the display unit 110 by the tip portion of the connecting member 128.

When the stand 120 is set to the second mode or the wall mounted mode, the first supporting member 121 may include a supporting member accommodating portion 121d provided on the lower surface to accommodate the second supporting member 126. The supporting member accommodating portion 121d may be provided in a size and/or shape corresponding to the size and/or shape of the second supporting member 126. The second supporting member 126 may overlap with the first supporting member 121 as it is accommodated in the supporting member accommodating portion 121d of the first supporting member 121.

The first supporting member 121 may include a coupling groove 121c to which the second supporting member 126 is rotatably coupled. The coupling groove 121c may be formed at both inner ends of the supporting member accommodating portion 121d. The second shaft 127 may be rotatably inserted into the coupling groove 121c.

The first shaft 122 may be inserted into the first coupling hole 121b of the first supporting member 121. Opposite ends of the first shaft 122 may be fixed to the first supporting member 121 by the shaft holder 123 when the first shaft 122 is inserted into the first coupling hole 121b of the first supporting member 121, and thus, the first shaft 122 is rotated together with the first supporting member 121.

End portions on both sides of the first supporting member 121 may have side covers 124 coupled thereto to make the appearance trimmed.

When the display apparatus 1 is placed on the floor, that is, when the stand 120 is set to the first stand mode, the second supporting member 126 may be provided to support the display unit 110 from the rear. In addition, when the display apparatus 1 is in close contact with the wall while being placed on the floor, that is, when the stand 120 is set to the second stand mode, the second supporting member 126 may overlap the first supporting member 121 and support the display unit 110 from the front with the first supporting member 121. On the other hand, when the display apparatus 1 is used in a wall mounted type, that is, when the stand 120 is set to the wall mounted mode, the second supporting member 126 may be pivoted on the display unit 110 to be directed down from the display unit 110 along with the first supporting member 121 while overlapping the first supporting member 121.

The second supporting member 126 may be rotatably coupled to the first supporting member 121. Specifically, the second supporting member 126 may be provided such that the second shaft 127 is inserted into the second coupling hole 126b and opposite end portions of the second shaft 127 may be rotatably inserted into the coupling groove 121c provided in the first supporting member 121.

When the stand 120 is set to the first stand mode or the second stand mode, the second supporting member 126 may include a seating portion 126a on which the lower surface of the connecting member 128 is seated. Thus, the second supporting member 126 may rotate about the connecting member 128 together with the first supporting member 121.

The second supporting member 126 may be rotated while being coupled to the first supporting member 121, or alternatively, the second supporting member 126 may be detached from the first supporting member 121 and coupled again thereto to allow the stand 120 to be set to the first stand mode or the second stand mode.

The connecting member 128 may be rotatably coupled to the first supporting member 121 as the first shaft 122 passes through the first coupling hole 121b of the first supporting member 121 and the third coupling hole 128b after a portion where the third coupling hole 128b is formed is inserted into the connecting member groove 121a of the first supporting member 121.

The connecting member 128 may include a display coupling hole 128a provided at one end portion of the connecting member 128 to be fixed to the display unit 110. The connecting member 128 may be fixed to the display unit 110 as the connecting member 128 is provided at the lower end portion of the display unit 110 and a coupling member such as a screw couples the display coupling hole 128a and the display unit 110.

The connecting member 128 may include a second guide portion 128c for continuously guiding a cable C guided from the first accommodating portion 114 of the display unit 110 through the first guide portion 115 to the lower portion of the display unit 110. The second guide portion 128c may have space of a size substantially similar to the cross-section of the cable C, such as the first guide portion 115. Accordingly, the display apparatus 1 according to an embodiment of the present disclosure may be installed by bringing the display unit 110 into close contact with the wall even if the cable C is connected to the rear of the display unit 110.

Although two connecting members 128 are shown to be provided in this embodiment, the number of the connecting members 128 is not limited thereto, and one or three or more connecting members 128 may be provided as necessary.

As described above, in the present embodiment, the mode of the stand 120 is changed as the second supporting member 126 rotates, however, the operation of the second supporting member 126 is not limited thereto, and the mode of the stand 120 may be changed by e.g., sliding movement of the second supporting member 126.

Referring to FIG. 5, the display unit 110 may include a first accommodating portion 114 formed to be recessed in the rear surface 113. The first accommodating portion 114 may receive a portion of at least one cable C electrically connected to the display unit 110. Specifically, the first accommodating portion 114 may include an accommodating portion (first accommodating portion shown on the right in FIG. 5) having a power connector 114a, to which the power cable connector C1 of the power cable C for supplying power to the display unit 110 is connected, and an accommodating portion (first accommodating portion shown on the left in FIG. 5) having a main board connector 114a, to which a main board cable connector C1 of a main board cable C for connecting an external device (not shown) such as a set top box to the display unit 110 is connected.

The first accommodating portion 114 may be formed to have a depth greater than the thickness of the cable C. That is, the first accommodating portion 114 may be formed to have a minimum depth corresponding to the thickness of the cable C.

The first accommodating portion 114 may include a first guide portion 115 for guiding the cable C accommodated in the first accommodating portion 114 to be pulled out of the display unit 110 through the lower surface of the display unit 110. The first guide portion 115 may accommodate other portion of the cable C than the portion of the cable C accommodated in the first accommodating portion 114. The first guide portion 115 may be depressed in the rear surface 113 of the display unit 110. The first guide portion 115 may have a grove shape. The first guide portion 115 may guide the cable C toward the stand 120 provided at the lower end portion of the display unit 110.

The first guide portion 115 may include a space having a shape substantially corresponding to the shape of the cross-section of the cable C. The first guide portion 115 may be provided to have a minimum depth corresponding to the thickness of the cable C. The first guide portion 115 may include an escape preventing portion 115a protruding from the inner surface of the first guide portion 115 to prevent the cable C from escaping out of the first guide portion 115. Although four of the escape preventing portion 115a are provided along the first guide portion 115, the number of escape preventing portions 115a is not limited thereto and may be changed as needed. The escape preventing portion 115a may extend from the rear surface 113 of the display unit 110 and have an end separated from the rear surface 113 of the display unit 110 to form a space. Through this space, the cable C may be inserted to the inside of the first guide portion 115.

In FIG. 5, the first guide portion 115 is shown as having a groove shape that is depressed in the rear surface 113 of the display unit 110, however, the first guide portion 115 is not limited thereto, and may be formed to protrude from the rear surface 113 to enclose the cable C. In this case, the first guide portion 115 may include a hollow formed inside the protruded portion of the first guide portion 115 to have a size corresponding to the diameter of the cable C.

According to this configuration, the display apparatus 1 according to the embodiment of the present disclosure, does not need to have a space for the cable C to pass between the display unit 110 and the wall 101, so that the display unit 110 may be brought into close contact with the wall 101. In addition, the cable C connected to the display unit 110 may be easily arranged.

The display unit 110 may include a second accommodating portion 116 formed to be depressed in the rear surface 113. The second accommodating portion 116 may accommodate the wall mount 103 supporting the display unit 110 when the display unit 110 is used in a wall mounted type and is installed on the wall.

The second accommodating portion 116 may be provided in a shape corresponding to the shape of the wall mount 103. The second accommodating portion 116 may have a minimum depth corresponding to the thickness of the wall mount 103.

The second accommodating portion 116 may be provided with a coupling portion 116a to which the wall mount 103 is coupled. The coupling portion 116a may include four or more Video Electronics Standards Association (VESA) holes or VESA mount holes according to the VESA standard. Dimensions of the VESA hall are width by (X) length and the unit is a millimeter (mm). The dimensions of the VESA hall may include 50×20, 75×35, 75×75, 75×50, 100×100, 100×50, 200×100, 200×50, 200×200 or 200×200 or more. The VESA hall may be formed in the rear surface 113 of the display unit 110 in a polygonal or “T” shape.

Alternatively, the coupling portion 116a may be provided for the dedicated wall mount 103 to be coupled thereto. The wall mount 103 may support the display unit 110 through the coupling portion 116a so that the display unit 110 may be installed on the wall 101.

If there is a fixing bracket (not shown) to which the wall mount 103 is detachably coupled, the second accommodating portion 116 may be provided to even accommodate the fixing bracket . Accordingly, the second accommodating portion 116 may have a shape corresponding to the outer shape of the wall mount 103 and the fixing bracket.

As described above, the display unit 110 according to an embodiment of the present disclosure may be installed to closely contact the wall 101 due to the first accommodating portion 114 and the second accommodating portion 116 that are recessed in the rear surface 113 of the display unit 110. That is, the display unit 110 according to the embodiment of the present disclosure may be provided to have all the portions other than the portions of the rear surface 113 where the first accommodating portion 114, the second accommodating portion 116 and the first guide portion 115 are formed are in close contact with the wall 101 when the display unit 110 is installed on the wall 101. Accordingly, the display apparatus 1 according to the embodiment of the present disclosure may provide the user with a feeling that the display unit 110 and the wall 101 are integrated with each other, so that the appearance may be enhanced and may prevent exposure of the rear surface 113 of the display unit 110, thereby making it neat in appearance.

The display unit 110 may include a wall mount cover 117 configured to cover the second accommodating portion 116 when the display unit 110 is installed on the floor with the stand 120 without being installed on the wall 101. That is, the wall mount cover 117 may cover the second accommodating portion 116 when the stand 120 is set to the first stand mode. Accordingly, the display unit 110 according to an embodiment of the present disclosure may prevent exposure of the second accommodating portion 116 while used in the stand type.

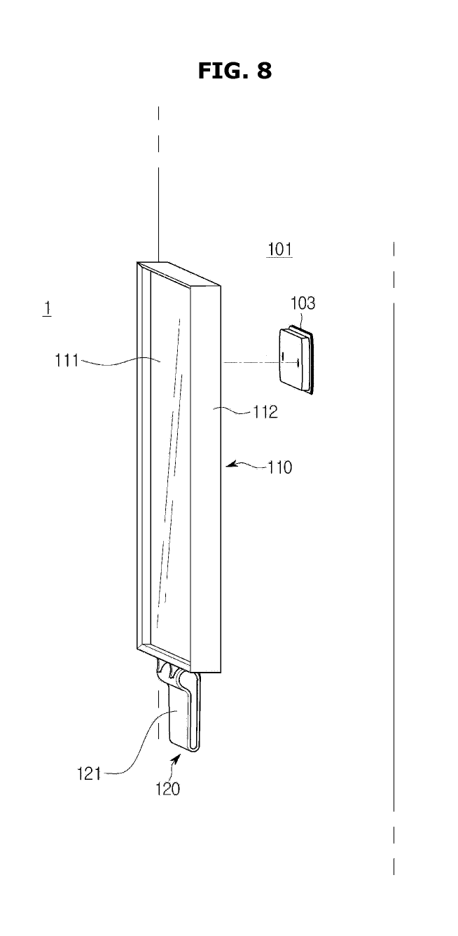

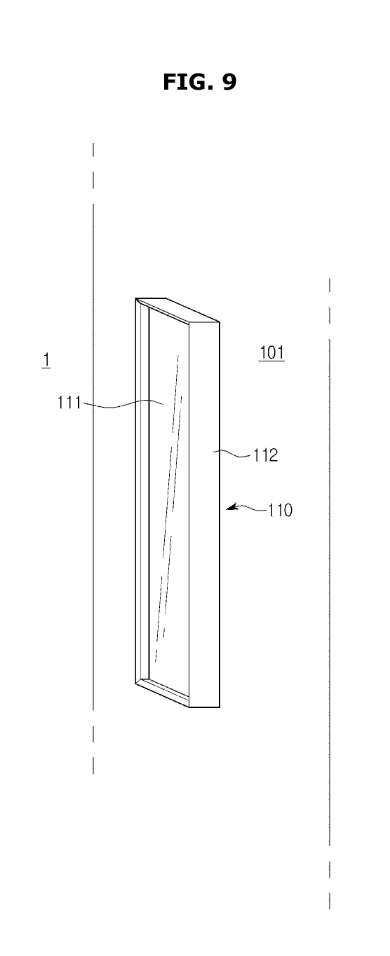

FIG. 6 is a perspective view illustrating the display unit 110 of the display apparatus 1 shown in FIG. 1 in close contact with the wall 101 while standing on the floor 102. FIG. 7 is a perspective view illustrating the display unit 110 of the display apparatus 1 shown in FIG. 1 installed in close contact with the wall 101. FIG. 8 is a perspective view illustrating the display unit 110 of the display apparatus 1 shown in FIG. 7 installed by a wall mount to closely contact the wall. FIG. 9 is a perspective view illustrating the stand 120 being separated from the display unit 110 in the display apparatus 1 shown in FIG. 7.

Referring to FIGS. 1 and 6 to 9, various installation methods of the display apparatus 1 of the present disclosure will be described.

Referring to FIG. 1, the display apparatus 1 may be installed with the display unit 110 standing on the floor 102 as the stand 120 is set to the first stand mode. At this time, the first supporting member 121 may support the display unit 110 in front of the display unit 110 and the second supporting member 126 may support the display unit 110 at the rear of the display unit 110.

Referring to FIG. 6, the display apparatus 1 may be installed with the display unit 110 standing on the floor 102 and closely contacting the wall 101 as the stand 120 is set to the second stand mode. The second supporting member 126 may be rotated about the first supporting member 121 to be accommodated in the supporting member accommodating portion 121d of the first supporting member 121. That is, the second supporting member 126 may overlap the first supporting member 121 to support the display unit 110 in front of the display unit 110 together with the first supporting member 121. As described above, the display apparatus 1 according to the embodiment of the present disclosure may be installed by bringing the display unit 110 into close contact with the wall 101 even at a place where the display unit 110 may not be hung on the wall 101.

Referring to FIGS. 7 and 8, the display apparatus 1 may be installed by bringing the display unit 110 into close contact with the wall through the wall mount 103 as the stand 120 is set to the wall mounted mode. At this time, the second supporting member 126 may be moved to be directed down from the display unit 110 together with the first supporting member 121 while being accommodated in the supporting member accommodating portion 121d of the first supporting member 121. Accordingly, the first supporting member 121 and the second supporting member 126 may be brought into close contact with the wall surface. In addition, the first supporting member 121 and/or the second supporting member 126 may be made with a transparent material to allow the wall 101 to be viewed, therefore, the display apparatus 1 may give a feeling of being integrated with the surrounding environment.

Referring to FIG. 9, the display apparatus 1 may be installed in close contact with the wall 101 with the stand 120 removed from the display unit 110.

According to the configuration as described above, the display apparatus 1 according to the embodiment of the present disclosure may be used in the stand type and the wall mounted type depending on the user's selection and may installed to closely contact the wall 101 to prevent the occurrence of a sense of alienation from the surrounding environment, and the appearance may be enhanced when the display apparatus 1 is installed to be supported by the wall 101.

The first supporting member 121 and the second supporting member 126 of the stand 120 may be rotatably provided so that the stand 120 may be installed in close contact with the wall 101 without being separated from the display unit 110.

According to the present disclosure, with rotatable first and second supporting members of a stand, the display apparatus may be installed by bringing the display unit into close contact with the wall.

According to the present disclosure, with first and second accommodating portions provided on the rear surface of the display unit, the display apparatus may be installed by bringing the display unit into close contact with the wall.

According to the present disclosure, since the display unit may be installed to closely contact the wall, the display apparatus may prevent exposure of the rear surface of the display unit and may give the user a feeling of being integrated with the wall , making it pleasant in appearance.

According to the present disclosure, with the rotatable first and second supporting members of the stand, the display apparatus may be installed by bringing the display unit into close contact with the wall without removing the stand from the display unit.

Although a few embodiments of the present disclosure have been shown and described, it would be appreciated by those skilled in the art that changes may be made in these embodiments without departing from the principles and spirit of the disclosure, the scope of which is defined in the claims and their equivalents.

What is claimed is:

1. A display apparatus, comprising:
a display unit configured to display content, the display unit having a first accommodating portion being depressed in a rear surface of the display unit, the first accommodating portion configured to accommodate a first portion of a cable connected to the display unit;
a first guide portion depressed in the rear surface of the display unit, the first guide portion, into which a second portion different from the first portion of the cable is inserted, the first guide portion configured to guide the second portion of the cable from the first accommodating portion to a side of the display unit; and
a stand detachably coupled to the display unit and configured to support the display unit on a mounting surface.

2. The display apparatus of claim 1, wherein the stand comprises:
a first supporting member configured to support the display unit, the first supporting member extending in a first direction from the display unit and configured to pivot on the display unit; and
a second supporting member configured to support the display unit, the second supporting member extending in a second direction opposite to the first direction from the display unit or overlapping with the first supporting member to support the display unit with the first supporting member by extending in the first direction.

3. The display apparatus of claim 1, wherein the stand is made with transparent material.

4. The display apparatus of claim 2, wherein the stand is configured to be set to:
a first stand mode to allow the display unit to be placed on a floor;
a second stand mode to allow the display unit to be disposed on the floor and brought close to a wall or brought in contact with the wall; and
a wall mounted mode to allow the display unit to be hung on the wall and brought close to a wall and brought in contact with the wall.

5. The display apparatus of claim 4, wherein the first supporting member is configured to support the display unit by being extending in the first direction, and wherein the second supporting member is configured to support the display unit by extending in the second direction, in response to the stand being set in the first stand mode.

6. The display apparatus of claim 4, wherein the second supporting member is accommodated in the first supporting member and is configured to support the display unit by extending the first direction together with the first supporting member, in response to the stand being set in the second stand mode.

7. The display apparatus of claim 4, wherein the second supporting member is accommodated in the first supporting member and is directed to a third direction different from the first direction and the second direction together with the first supporting member, in response to the stand being set in the wall mounted mode.

8. The display apparatus of claim 2, wherein the second supporting member is rotatably coupled to the first supporting member.

9. The display apparatus claim 2, wherein:
the stand includes a connecting member having a fixing portion to which the first supporting member is rotatably coupled, the fixing portion being fixed to the display unit, and
the first supporting member includes a rotation restricting portion configured to guide rotation of the first supporting member.

10. The display apparatus of claim 2, wherein the first supporting member includes a supporting member accommodating portion provided on a lower surface of the first supporting member and configured to accommodate the second supporting member in response to the second supporting member overlapping the first supporting member.

11. The display apparatus of claim 10, wherein the first supporting member includes a coupling groove to which the second supporting member is rotatably coupled, the coupling groove being provided in the supporting member accommodating portion.

12. The display apparatus of claim 1, wherein:
the first guide portion is configured to guide the cable to the stand provided on the lower side of the display unit, and
the stand includes a second guide portion configured to guide the cable guided by the first guide portion to a lower portion of the stand.

13. The display apparatus of claim 1, wherein at least one of the first accommodating portion and the first guide portion is configured to have a minimum depth corresponding to a thickness of the cable.

14. The display apparatus of claim 1, wherein the first guide portion includes an escape preventing portion protruding from an inner surface of the first guide portion, the escape preventing portion configured to prevent the cable from escaping out of the first guide portion.

15. The display apparatus of claim 1, wherein the display unit includes a side frame made with a transparent material.

16. A display unit, comprising:
a frame;
a first accommodating portion having a connector configured to be connected to a cable, the first accommodating portion being formed on a rear surface to accommodate a first portion of the cable connected to the connector;
a second accommodating portion formed at an upper portion of the rear surface to accommodate a wall mount; and
a first guide portion provided on the rear surface to insert a second portion different from the first portion of the cable, the first guide portion provided to guide the second portion of the cable from the first accommodating portion to a side of the frame,
wherein a remaining portion of the rear surface other than portions of the rear surface where the first accommodating portion, the second accommodating portion, and the first guide portion are formed is in contact with a wall or in proximity of the wall when the display unit is mounted on the wall.

17. The display unit of claim 16, wherein the first guide portion includes a groove depressed in the rear surface.

18. The display unit of claim 16, wherein at least one of the first accommodating portion and the first guide portion is configured to have a minimum depth corresponding to the thickness of the cable.

19. The display unit of claim 16, wherein the first guide portion includes an escape preventing portion protruding from an inner surface of the first guide portion, the escape preventing portion configured to prevent the cable from escaping out of the first guide portion.

20. The display unit of claim 16, wherein the frame is made with a transparent material.
